(19) United States
(12) Patent Application Publication
(10) Pub. No.: US 2026/0324273 A1
(43) Pub. Date: Oct. 15, 2026

(54) BONDING DEVICE, DISPLAY PANEL BONDING METHOD USING THE SAME, AND ELECTRONIC DEVICE

(71) Applicant: Samsung Display Co., Ltd., Yongin-si (KR)

(72) Inventors: DONGJIN PARK, Yongin-si (KR); YOUNGSU KIM, Yongin-si (KR); KISANG YOO, Yongin-si (KR); JAESANG LEE, Yongin-si (KR); JOON-IK LEE, Yongin-si (KR); SOMI JUNG, Yongin-si (KR)

(21) Appl. No.: 19/642,485

(22) Filed: Apr. 8, 2026

(30) Foreign Application Priority Data
Apr. 14, 2025 (KR) 10-2025-0047937

(51) Int. Cl. H10K 71/50; H10K 59/12; H10K 59/80

(52) U.S. Cl. CPC H10K 71/50; H10K 59/1201; H10K 59/873

(57) ABSTRACT

A bonding device includes: a first stage including a plurality of edge pressing rods and a plurality of corner pressing rods; a second stage on the first stage and having a plurality of edge guide openings and a plurality of corner guide openings; a pressing pad on the second stage; and a window fixing chuck on the pressing pad. When viewed on a plane, the edge pressing rods respectively pass through the edge guide openings, and the corner pressing rods respectively pass through the corner guide openings.

### CROSS-REFERENCE TO RELATED APPLICATIONS

The present application claims priority to and the benefit of Korean Patent Application No. 10-2025-0047937, filed on Apr. 14, 2025, in the Korean Intellectual Property Office, the entire disclosure of which is incorporated herein by reference.

### BACKGROUND

### 1. Field

Aspects of embodiments of the present disclosure relate to a bonding device, a display panel bonding method using the same, and an electronic device.

### 2. Description of the Related Art

Generally, an electronic device, which provides an image to a user, such as a smart phone, a digital camera, a laptop computer, a navigation system, or a smart television, includes a display device for displaying an image. The display device generates an image and provides the generated image to a user through a display screen.

Presently, with the development of display technology, various types of display devices are being developed. For example, a display device having a curved side surface and displaying an image on a portion of the curved side surface, is being developed.

A display device includes a display module that displays an image and a window disposed on the display module to protect the display module. When a side of the display device has a curved surface, a side of the display module and a side of the window also have curved surfaces.

### SUMMARY

Embodiments of the present disclosure provide a bonding device that prevents or reduces a bonding failure between a display module and a window and a display panel bonding method using the same.

Embodiments of the present disclosure also provide an electronic device including a window and a display module manufactured by a bonding device as described above.

A bonding device, according to an embodiment of the present disclosure, includes a first stage having a plurality of edge pressing rods and a plurality of corner pressing rods, a second stage on the first stage and having a plurality of edge guide openings and a plurality of corner guide openings, a pressing pad on the second stage, and a window fixing chuck on the pressing pad. When viewed on a plane, the edge pressing rods respectively pass through the edge guide openings, and the corner pressing rods respectively pass through the corner guide openings.

In an embodiment, the edge pressing rods and the corner pressing rods may be integrally formed.

In an embodiment, the edge pressing rods and the corner pressing rods may be configured to independently reciprocate in a vertical direction.

In an embodiment, the pressing pad includes corner portions, edge portions between the corner portions, and a central portion surrounded, when viewed on the plane, by the corner portions, and the corner portions may be configured to be controlled independently from the edge portions and the central portion.

In an embodiment, the central portion may be higher than the corner portions and the edge portions.

In an embodiment, when viewed on the plane, the edge guide openings and the corner guide openings may be alternately arranged along a circumferential direction of the second stage.

In an embodiment, when viewed on the plane, upper surfaces of the edge pressing rods may have a rectangular shape, and upper surfaces of the corner pressing rods may have an arc shape.

In an embodiment, wherein, when viewed on the plane, at least one of the edge guide openings may be between the corner guide openings in a circumferential direction of the second stage.

In an embodiment, the bonding device may further include a chamber in which the first stage, the second stage, the pressing pad, and the window fixing chuck are mounted.

In an embodiment, when viewed on the plane, a corner portion of the pressing pad may have a rounded shape.

In an embodiment, when viewed on the plane, an edge portion connecting the corner portion of the pressing pad may have a rounded edge shape.

In an embodiment, a lower surface of the window fixing chuck may have a recessed portion therein, and the recessed portion may correspond to the rounded shape of the pressing pad.

A display panel bonding method, according to an embodiment of the present disclosure, includes preparing a first stage having a plurality of edge pressing rods and a plurality of corner pressing rods, disposing, on the first stage, a second stage having a plurality of edge guide openings and a plurality of corner guide openings, disposing, on the second stage, a pressing pad having corner portions having a rounded shape and edge portions connecting the corner portions having a rounded edge shape when viewed on a plane, disposing a window fixing chuck on the pressing pad, disposing a window on a recessed portion in a lower surface of the window fixing chuck, disposing a display module on the pressing pad, bonding the window and the display module, pressing the window and the display module by a third stage on the window fixing chuck, and pressing the edge portion of the pressing pad by the edge pressing rods respectively passing through the edge guide openings and pressing the corner portions of the pressing pad by the corner pressing rods respectively passing through the corner guide openings.

In an embodiment, the display panel bonding method may further include pressing the window and the display module by the third stage after the pressing of the edge portions of the pressing pad by the edge pressing rods and the pressing of the corner portions of the pressing pad by the corner pressing rods.

In an embodiment, the edge pressing rods and the corner pressing rods may integrally reciprocate in a vertical direction.

In an embodiment, the edge pressing rods and the corner pressing rods may each independently reciprocate in a vertical direction.

In an embodiment, when viewed on the plane, upper surfaces of the edge pressing rods may have a rectangular shape, and upper surfaces of the corner pressing rods may have an arc shape.

In an embodiment, when viewed on the plane, at least one of the edge guide openings may be defined between the corner guide holes in a circumferential direction of the second stage.

In an embodiment of the present disclosure, an electronic device includes a window and a display module. The window and the display module are bonded by preparing a first stage having a plurality of edge pressing rods and a plurality of corner pressing rods, disposing, on the first stage, a second stage having a plurality of edge guide openings and a plurality of corner guide openings, disposing, on the second stage, a pressing pad having corner portions having a rounded shape and edge portions connecting the corner portions having a rounded edge shape when viewed on a plane, disposing a window fixing chuck on the pressing pad, disposing the window on a recessed portion in a lower surface of the window fixing chuck, disposing the display module on the pressing pad, bonding the window and the display module, pressing the window and the display module by a third stage disposed on the window fixing chuck, and pressing the edge portions of the pressing pad by the edge pressing rods respectively passing through the edge guide openings and pressing the corner portions of the pressing pad by the corner pressing rods respectively passing through the corner guide openings.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, explain aspects and features of the present disclosure. In the drawings:

FIG. 1 is a block diagram of an electronic device according to an embodiment of the present disclosure;

FIG. 2 illustrates schematic views of electronic devices according to embodiments of the present disclosure;

FIG. 3 is a perspective view of an electronic device manufactured by using a bonding device according to an embodiment of the present disclosure;

FIG. 4 is a schematic cross-sectional view of a display module and a window of the electronic device illustrated in FIG. 3;

FIG. 5 is a cross-sectional view of the display module illustrated in FIG. 4;

FIG. 6 is a cross-sectional view of the display panel illustrated in FIG. 5;

FIG. 7 is a perspective view of a bonding device according to an embodiment of the present disclosure;

FIGS. 8 and 9 are plan views of a second stage of a bonding device according to an embodiment of the present disclosure;

FIG. 10 is a perspective view of a bonding device according to an embodiment of the present disclosure;

FIG. 11 is a cross-sectional view taken along the line I-I' in FIG. 7;

FIG. 12 is a cross-sectional view taken along the line II-II' in FIG. 7;

FIG. 13 is a diagram illustrating a state in which a display module is disposed on a pressing pad for a process of bonding a display module and a window;

FIG. 14 is a diagram illustrating a portion of a bonding device according to an embodiment of the present disclosure; and

FIGS. 15 to 17 are diagrams illustrating a display panel bonding method according to an embodiment of the present disclosure.

### DETAILED DESCRIPTION

In this specification, it will be understood that when an element (or a region, a layer, a portion, or the like) is referred to as being "on", "connected to", or "coupled to" another element, it may be directly disposed on, connected to, or coupled to the other element, or other elements may be disposed therebetween.

Like reference numerals or symbols refer to like elements throughout. In the drawings, the thickness, ratio, and size of the elements may be exaggerated for effectively describing the technical contents. As used herein, the term "and/or" includes any and all combinations of one or more of the associated listed elements. Further, the use of "may" when describing embodiments of the present disclosure relates to "one or more embodiments of the present disclosure." Expressions, such as “at least one of” and “any one of,” when preceding a list of elements, modify the entire list of elements and do not modify the individual elements of the list. For example, the expression "at least one of a, b, or c" indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms "substantially," "about," and similar terms are used as terms of approximation and not as terms of degree, and are intended to account for the inherent variations in measured or calculated values that would be recognized by those of ordinary skill in the art

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the present disclosure. Similarly, a second element, component, region, layer or section could be termed a first element, component, region, layer or section. In this specification, the singular expressions "a", "an" and "the" are intended to include the plural forms as well, unless the context clearly indicates otherwise.

In addition, the terms "below", “under”, "on the lower side", "above", “over”, "on the upper side", or the like may be used to describe the relationships between the elements illustrated in the drawings. These terms are relative concepts and are described on the basis of the directions indicated in the drawings.

It will be further understood that the terms "comprises, includes, has" and/or "comprising, including, having", when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the accompanying drawings.

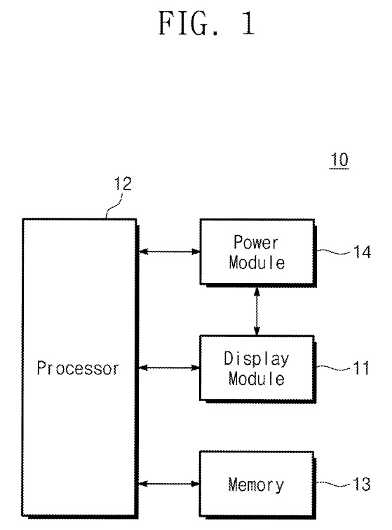

FIG. 1 is a block diagram of an electronic device according to an embodiment of the present disclosure.

Referring to FIG. 1, an electronic device 10, according to an embodiment, may include a display module (DM) 11, a processor 12, a memory 13, and a power module 14.

The processor 12 may include at least one from among a central processing unit (CPU), an application processor (AP), a graphic processing unit (GPU), a communication processor (CP), an image signal processor (ISP), and a controller. The processor 12 may process an image signal to provide the processed image to a display device.

The memory 13 may store data information required for an operation of the processor 12 or the display module 11. When the processor 12 executes an application stored in the memory 13, an image data signal and/or an input control signal may be transferred to the display module 11, and the display module 11 may process the received signal and output image information through a display screen.

The power module 14 may include a power supply module, such as a power adaptor or a battery device, and a power conversion module that converts power supplied by the power supply module to generate power required for an operation of the electronic device 10.

At least one of individual components of the electronic device 10 may be included in a display device according to the embodiments. Additionally, from among individual modules that are functionally included in a single module, some may be included in the display device, and others may be provided separately from the display device. For example, the display device may include the display module 11, and the processor 12, the memory 13, and the power module 14 may be provided in the form of other devices than the display device in the electronic device 10.

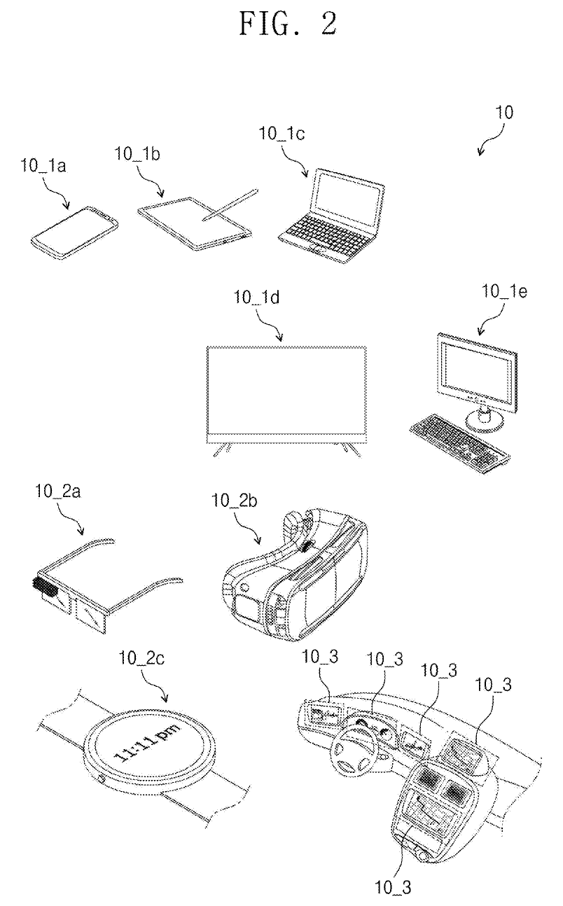

FIG. 2 illustrates schematic views of electronic devices according to embodiments of the present disclosure.

Referring to FIG. 2, various electronic devices, to which display devices according to embodiments may be applied, may include not only an image displaying electronic device, such as a smart phone 10_1a, a tablet PC 10_1b, a laptop 10_1c, a TV 10_1d, or a desk monitor 10_1e, but also a wearable electronic device including a display module, such as smart glasses 10_2a, a head-mounted display 10_2b, or a smart watch 10_2c, and a vehicular electronic device 10_3 including a display module, such as a car dashboard, a center fascia, a center information display (CID) disposed in a dashboard, or a room mirror display.

In the above, description has been made with reference to embodiments of the present disclosure, but those skilled or of ordinary skill in the art may understand that various modifications and changes may be made to the present disclosure insofar as such modifications and changes do not depart from the spirit and technical scope of the present disclosure set forth in the claims and their equivalents, described later. The electronic device 10 (see, e.g., FIG. 1) may include a window WIN (see, e.g., FIG. 4) and a display module DM (see, e.g., FIG. 4), which are manufactured by a display panel bonding device according to embodiments of the present disclosure.

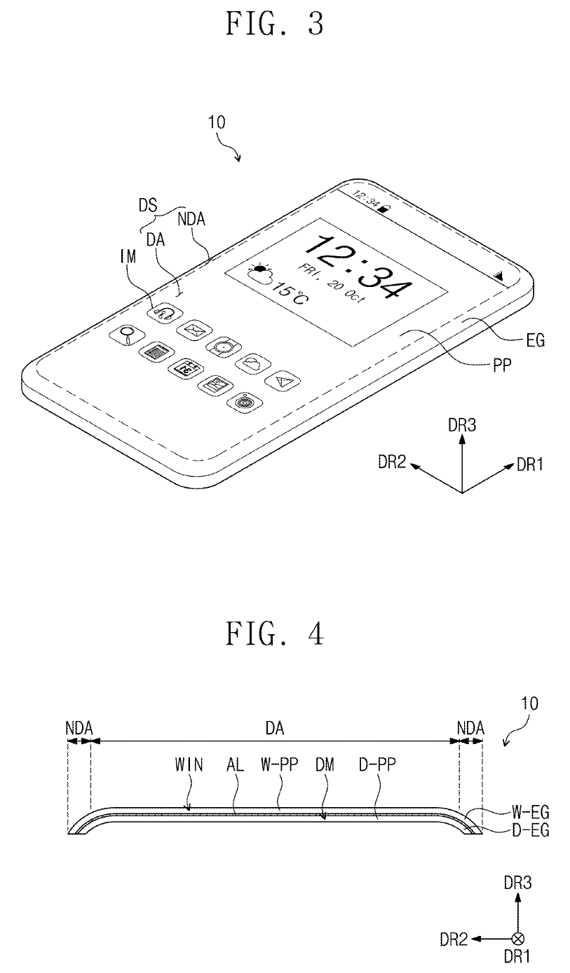

FIG. 3 is a perspective view of an electronic device manufactured by using a bonding device according to an embodiment of the present disclosure.

Referring to FIG. 3, the electronic device 10, according to an embodiment of the present disclosure, may have long sides parallelly extending in a first direction DR1 and short sides parallelly extending in a second direction DR2 crossing the first direction DR1. The corners of the electronic device 10 connecting the long sides and short sides of the electronic device 10 may have a curved shape. The corners of the electronic device 10 having a curved shape may be defined as round corners. The shape of the electronic device 10 may be defined as a rounded corner quadrilateral.

Hereinafter, a direction substantially perpendicular to a plane defined by a first direction DR1 and a second direction DR2 is defined as a third direction DR3. In this specification, the term "when viewed on a plane" refers to a state viewed from (or in) the third direction DR3.

Images IM generated in the electronic device 10 may be provided to (e.g., emitted toward) a user through an upper surface of the electronic device 10 as viewed from the third direction DR3. The upper surface of the electronic device 10 may have a display region DA and a non-display region NDA surrounding (e.g., extending around a periphery of) the display region DA. The display region DA may be where an image is displayed, and the non-display region NDA may be where an image is not displayed. The non-display region NDA may surround the display region DA and may define a border of the electronic device 10 that is printed in a selected color.

The upper surface of the electronic device 10 may have a flat surface portion PP and an edge portion EG having a curved surface. The flat surface portion PP may have a flat surface defined by first and second directions DR1 and DR2. The edge portion EG may surround (e.g., may extend around a periphery of) the flat surface portion PP. The edge portion EG may extend downwardly from the flat surface portion PP to form a curved surface. The edge portion EG may have a selected (or reference) curvature. The display region DA may be defined in the flat surface portion PP and a portion of the edge portion EG adjacent to the flat surface portion PP.

FIG. 4 is a schematic cross-sectional view of a display module and a window of the electronic device illustrated in FIG. 3.

As an example, FIG. 4 illustrates a cross-section of the display module DM and the window WIN as viewed from a first direction DR1.

Referring to FIG. 4, the electronic device 10 may include the display module DM and the window WIN disposed on the display module DM. The window WIN may protect the display module DM from external scratches and impacts.

The display module DM may have a flat surface portion D-PP and an edge portion D-EG extending from the flat surface portion D-PP and having a curved surface. The window WIN may have a flat surface portion W-PP and an edge portion W-EG extending from the flat surface portion W-PP and having a curved surface.

When viewed on a plane, the flat surface portion D-PP of the display module DM and the flat surface portion W-PP of the window WIN may overlap each other. When viewed on a plane, the edge portion D-EG of the display module DM and the edge portion W-EG of the window WIN may overlap each other.

The flat surface portion D-PP of the display module DM and the flat surface portion W-PP of the window WIN may correspond to the flat surface portion PP of the electronic device 10. The edge portion D-EG of the display module DM and the edge portion W-EG of the window WIN may correspond to the edge portion EG of the electronic device 10.

The display module DM and the window WIN may have a shape corresponding to the electronic device 10 illustrated in FIG. 3. For example, the display module DM and the window WIN may have a rounded corner quadrilateral shape corresponding to the electronic device 10.

An adhesive layer AL may be disposed between the display module DM and the window WIN. The display module DM and the window WIN may be bonded to each other by the adhesive layer AL. The adhesive layer AL may include a pressure sensitive adhesive (PSA) or an optically clear adhesive (OCA), but the type of the adhesive is not limited thereto.

The display region DA may be defined in the flat surface portion PP and a portion of the edge portion EG adjacent to the flat surface portion PP. Accordingly, a portion of the edge portion EG adjacent to the flat surface portion PP may display an image.

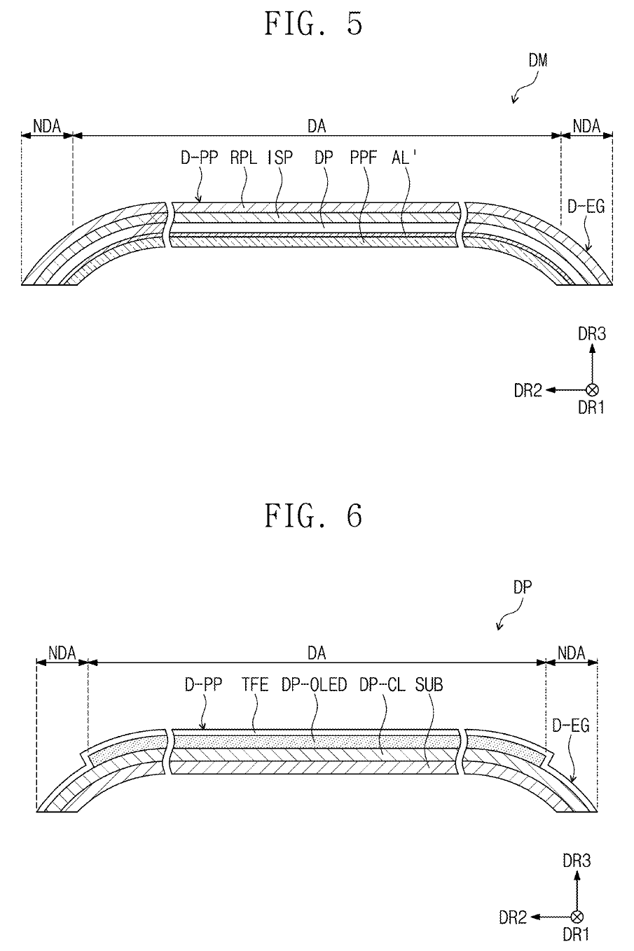

FIG. 5 is a cross-sectional view of the display module illustrated in FIG. 4.

As an example, FIG. 5 illustrates a cross-section of the display module DM as viewed from the first direction DR1.

Referring to FIG. 5, the display module DM may include the display panel DP, an input sensing unit ISP, an anti-reflection layer RPL, a panel protection film PPF, and an adhesive layer AL'.

The display panel DP, according to an embodiment of the present disclosure, may be a light-emitting display panel. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, and the like. Hereinafter, the display panel DP is described as an organic light-emitting display panel, but the present disclosure is not limited thereto.

The input sensing unit ISP may be disposed on the display panel DP. The input sensing unit ISP may include a plurality of sensing units for sensing an external input in, for example, a capacitive manner. The input sensing unit ISP may be manufactured directly on the display panel DP during manufacturing of the electronic device 10. However, an embodiment of the present disclosure is not limited thereto, and the input sensing unit ISP may be manufactured as a separate panel from the display panel DP and attached to the display panel DP by an adhesive layer.

The anti-reflection layer RPL may be disposed on the input sensing unit ISP. The anti-reflection layer RPL may be manufactured directly on the input sensing unit ISP during the manufacturing of the electronic device 10. However, an embodiment of the present disclosure is not limited thereto, and the anti-reflection layer RPL may be manufactured as a separate panel and attached to the input sensing unit ISP by an adhesive layer.

The anti-reflection layer RPL may be defined as an external light anti-reflection film. The anti-reflection layer RPL may reduce the reflectance for external light incident from above the electronic device 10 toward the display panel DP. The external light may be invisible to a user due to the anti-reflection layer RPL.

When the external light propagating toward the display panel DP is reflected by the display panel DP and provided again to an external user, the user may view the external light as being reflected by a mirror. To prevent this phenomenon, the anti-reflection layer RPL may include, for example, a plurality of color filters that display the same color as the pixels of the display panel DP.

The color filters may filter the external light to exhibit the same colors as those of the pixels. In such an embodiment, the external light may be invisible to the user. However, an embodiment of the present disclosure is not limited thereto, and the anti-reflection layer RPL may include a phase retarder and/or a polarizer to reduce the external light reflectance.

The panel protection film PPF may be disposed under the display panel DP. The panel protection film PPF may protect the lower portion of the display panel DP. The panel protection film PPF may include a flexible plastic material such as polyethylene terephthalate (PET).

The adhesive layer AL' may be disposed between the display panel DP and the panel protection film PPF. The display panel DP and the panel protection film PPF may be bonded to each other by the adhesive layer AL'. The adhesive layer AL' may include a pressure-sensitive adhesive or an optically transparent adhesive, but the type of the adhesive is not limited thereto.

FIG. 6 is a cross-sectional view of the display panel illustrated in FIG. 5.

As an example, FIG. 6 illustrates a cross-section of the display panel DP as viewed from the first direction DR1.

Referring to FIG. 6, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The display panel DP may have the flat surface portion D-PP and an edge portion D-EG extending from the flat surface portion D-PP and having a curved surface. As an example, the flat surface portion D-PP and the edge portion D-EG of the display panel DP are illustrated with the same symbols as the flat surface portion D-PP and the edge portion D-EG of the display module DM.

The substrate SUB may have the display region DA and the non-display region NDA surrounding (e.g., extending around a periphery of) the display region DA. The substrate SUB may include glass or a flexible plastic material, such as polyimide (PI).

The display element layer DP-OLED may be disposed on the display region DA. The display element layer DP-OLED may generate an image. The display element layer DP-OLED may be disposed in the flat surface portion D-PP and within a portion of the edge portion D-EG adjacent to the flat surface portion D-PP. Accordingly, an image may be displayed in the portion of the edge portion D-EG adjacent to the flat surface portion D-PP.

A plurality of pixels may be arranged on the circuit element layer DP-CL and the display element layer DP-OLED. Each of the pixels may include a transistor disposed on the circuit element layer DP-CL and a light-emitting element that is disposed on the display element layer DP-OLED and connected to the transistor.

The thin-film encapsulation layer TFE may be disposed above the circuit element layer DP-CL to cover the display element layer DP-OLED. The-thin film encapsulation layer TFE may protect the pixels from moisture, oxygen, and external foreign substances.

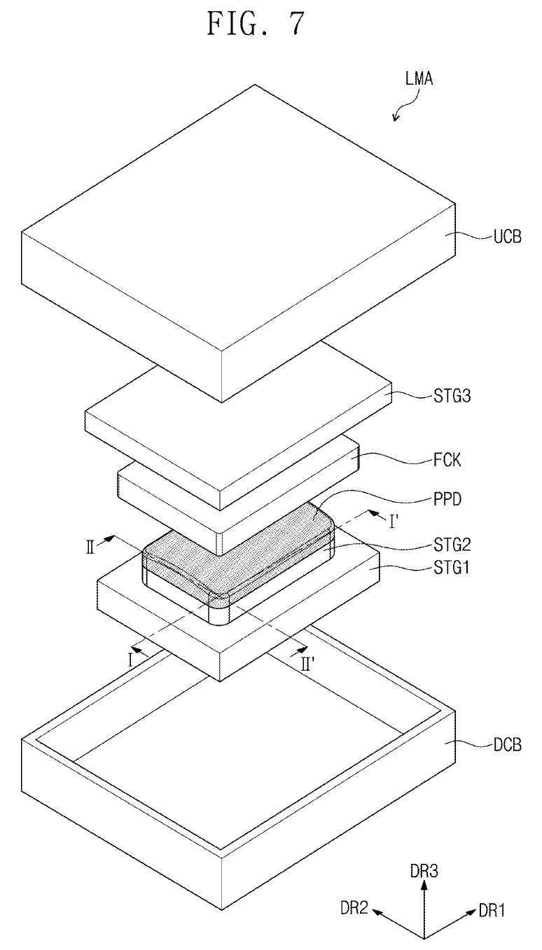

FIG. 7 is a perspective view of a bonding device according to an embodiment of the present disclosure.

Referring to FIG. 7, a bonding device LMA, according to an embodiment of the present disclosure, may be defined as a lamination device. The bonding device LMA may include a first stage STG1, a second stage STG2, a pressing pad PPD, a window fixing chuck FCK, an upper chamber UCB, and a lower chamber DCB.

The second stage STG2 may be disposed on the first stage STG1. The first stage STG1 and the second stage STG2 will be described, in detail, with reference to FIGS. 10 to 12.

The pressing pad PPD may be disposed on the second stage STG2. The pressing pad PPD may be disposed between the window fixing chuck FCK and the second stage STG2. The pressing pad PPD may extend longer in a first direction DR1 than in a second direction DR2. The pressing pad PPD may include a material the shape of which may be easily deformed and restored. For example, the pressing pad PPD may include rubber, silicone, or polyurethane, but materials of the pressing pad PPD are not limited thereto.

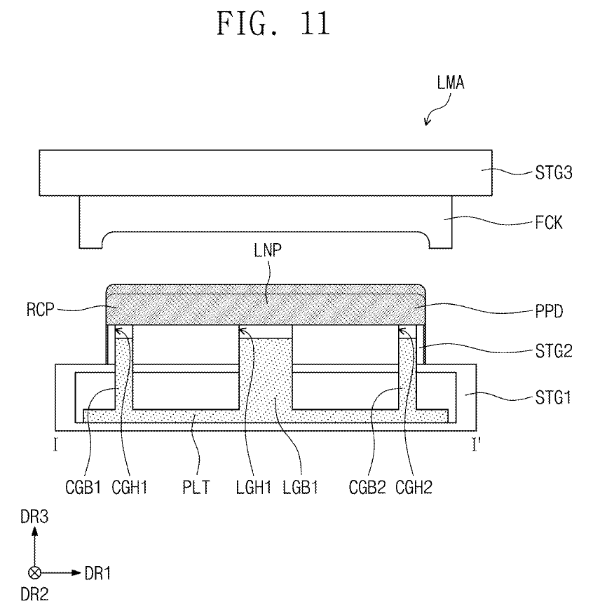

The window fixing chuck FCK may be disposed on the pressing pad PPD. The window fixing chuck FCK may extend longer in the first direction DR1 than in the second direction DR2. The window fixing chuck FCK may have a recessed portion defined in a lower surface thereof, and a window may be disposed in the recessed portion. This configuration will be illustrated in FIG. 11 below.

The first stage STG1, the second stage STG2, the pressing pad PPD, the window fixing chuck FCK, and the third stage STG3 are mounted in the upper chamber UCB and the lower chamber DCB. The lower chamber DCB may have an accommodating space in which the first stage STG1 may be mounted. The upper chamber UCB may have an accommodating space in which the window fixing chuck FCK and the third stage STG3 may be mounted.

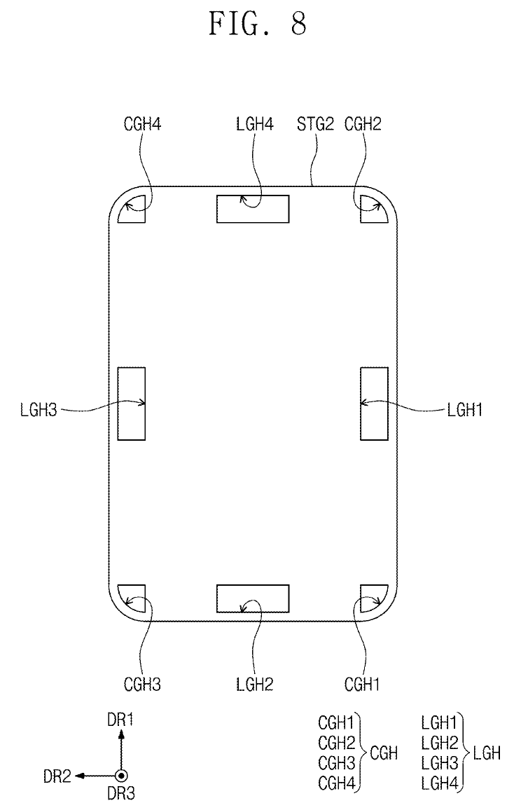

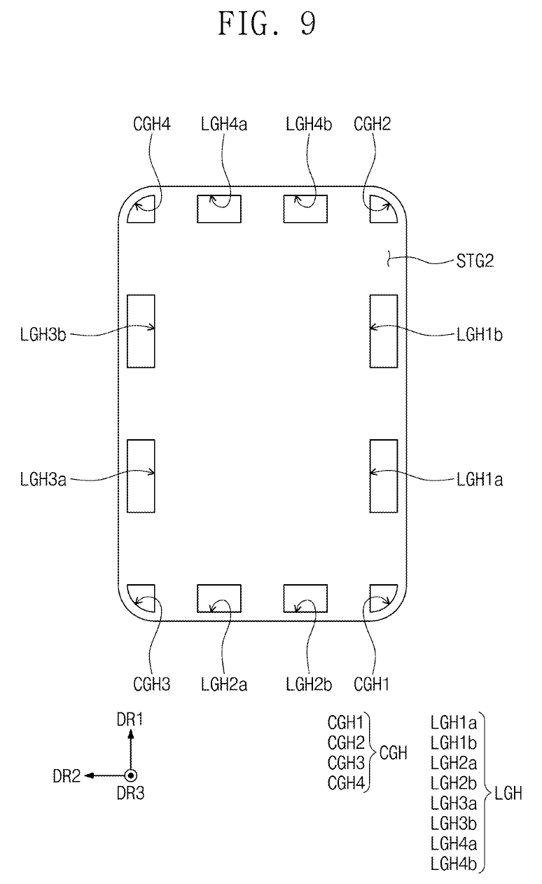

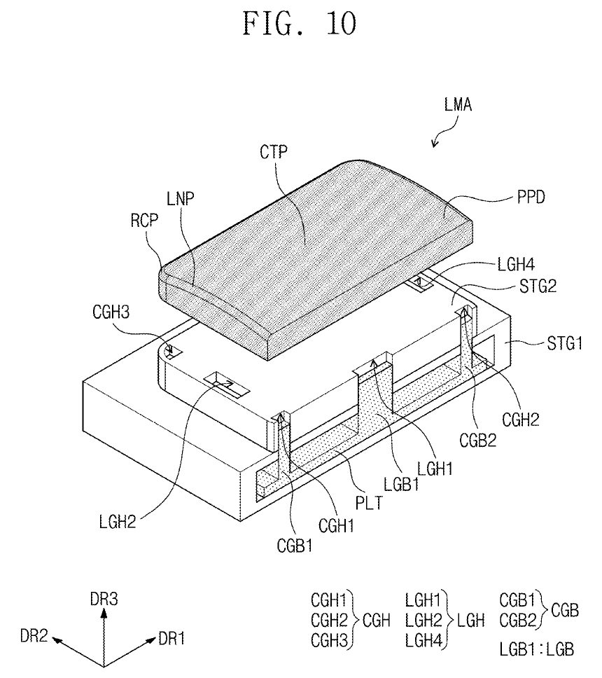

FIGS. 8 and 9 are plan views of a second stage of a bonding device according to an embodiment of the present disclosure.

Referring to FIGS. 7 and 8, the second stage STG2 may be disposed under the pressing pad PPD. A plurality of edge guide holes (e.g., edge guide openings) LGH and a plurality of corner guide holes (e.g., corner guide openings) CGH may be defined in the second stage STG2. When viewed on a plane, the edge guide holes LGH and the corner guide holes CGH may be defined (or arranged) alternately along the circumferential direction of the second stage STG2.

For example, a first corner guide hole CGH1, a third corner guide hole CGH3, a fourth corner guide hole CGH4, and a second corner guide hole CGH2 may be defined in the second stage STG2 in a clockwise direction. A first edge guide hole LGH1, a second edge guide hole LGH2, a third edge guide hole LGH3, and a fourth edge guide hole LGH4 may be defined in the second stage STG2 in a clockwise direction. The edge guide holes LGH may be defined between the corner guide holes CGH.

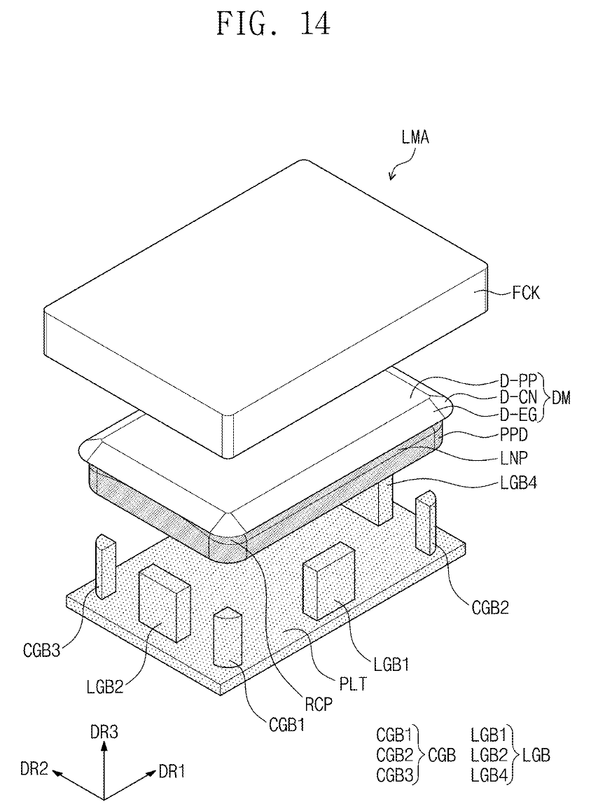

When viewed on a plane, the edge guide holes LGH may have a rectangular shape, and the corner guide holes CGH may have an arc shape at the corners of the second stage STG2. FIG. 8 illustrates an embodiment in which the number of the edge guide holes LGH and the number of the corner guide holes CGH are each four, but as long as edge pressing rods LGB (see, e.g., FIG. 14), to be described later, may respectively pass through the edge guide holes LGH to press the pressing pad PPD and corner pressing rods CGB (see, e.g., FIG. 14) may respectively pass through the corner guide holes CGH to press the pressing pad PPD, the number of the edge guide holes LGH and the number of the corner guide holes CGH are not limited thereto.

The edge guide holes LGH and the corner guide holes CGH may be defined at edge portions and corner portions, respectively, and may not be integrally formed along the circumference of the second stage STG2.

Through the edge guide holes LGH, the edge pressing rods LGB, which will be described later, may respectively pass through the edge guide holes LGH to press the pressing pad PPD. Through the corner guide holes CGH, the corner pressing rods CGB, which will be described later, may respectively pass through the corner guide holes CGH to press the pressing pad PPD.

Referring to FIGS. 7 and 9, when viewed on a plane, at least one of the edge guide holes LGH may be defined between the corner guide holes CGH in the circumferential direction of a second stage STG2a.

For example, first edge guide holes LGH may be defined between the first corner guide hole CGH1 and the second corner guide hole CGH2 in a clockwise direction. Second edge guide holes LGH may be defined between the first corner guide hole CGH1 and the third corner guide hole CGH3. Third edge guide holes LGH may be defined between the third corner guide hole CGH3 and the fourth corner guide hole CGH4. Fourth edge guide holes LGH may be defined between the second corner guide hole CGH2 and the fourth corner guide hole CGH4.

Although two edge guide holes LGH are exemplarily illustrated as being disposed between the corner guide holes CGH, the number of the edge guide holes LGH is not limited thereto as long as the edge pressing rods LGB (see, e.g., FIG. 14) may press the pressing pad PPD through the edge guide holes LGH. Compared to the second stage STG2 shown in FIG. 8, the edge guide holes LGH are disposed in plurality between the corner guide holes CGH, and therefore, when the edge pressing rods LGB press the pressing pad PPD through the edge guide holes LGH, uniform pressure may be transferred to the edge portions of the pressing pad PPD.

FIG. 10 is a perspective view of a bonding device according to an embodiment of the present disclosure. In FIG. 10, for convenience of explanation, the edge guide holes LGH are illustrated as a first edge guide hole LGH1, a second edge guide hole LGH2, and a fourth edge guide hole LGH4. The corner guide holes CGH are illustrated as a first corner guide hole CGH1, a second corner guide hole CGH2, and a third corner guide hole CGH3. The corner pressing rods CGB are illustrated as a first corner pressing rod CGB1 and a second corner pressing rod CGB2, and a first edge pressing rod LGB1 is illustrated from among the edge pressing rods LGB.

Referring to FIG. 10, a plurality of edge pressing rods LGB and a plurality of corner pressing rods CGB may be disposed inside the first stage STG1. FIG. 10 exemplarily illustrates the first corner pressing rod CGB1, the second corner pressing rod CGB2, and the first edge pressing rod LGB1. When viewed on a plane, the edge pressing rods LGB may respectively pass through edge guide holes. The corner pressing rods CGB may respectively pass through the corner guide holes CGH.

The edge pressing rods LGB and the corner pressing rods CGB may be integrally formed. The edge pressing rods LGB and the corner pressing rods CGB may be connected to a plate PLT and integrally formed therewith. Because the edge pressing rods LGB and the corner pressing rods CGB are integrally formed, the edge pressing rods LGB and the corner pressing rods CGB may simultaneously press the pressing pad PPD.

FIG. 10 illustrates an embodiment in which the edge pressing rods LGB and the corner pressing rods CGB are integrally formed, but in another embodiment, the edge pressing rods LGB and the corner pressing rods CGB may not be connected to the plate PLT and may independently reciprocate in a vertical direction.

In the pressing pad PPD, corner portions RCP, edge portions LNP disposed between the corner portions RCP, and a central portion CTP surrounded by the edge portions LNP may be defined. The central portion CTP may be disposed higher than (e.g., above) the edge portions LNP and the corner portions RCP. For example, the corner portions RCP of the pressing pad PPD may have a rounded shape. The edge portions LNP of the pressing pad PPD may have a rounded edge shape.

When the edge pressing rods LGB and the corner pressing rods CGB independently reciprocate, the corner portions RCP of the pressing pad PPD may be controlled independently from the edge portions LNP and the central portion CTP.

FIG. 11 is a cross-sectional view taken along the line I-I' in FIG. 7.

Referring to FIG. 11, the first corner pressing rod CGB1 may pass through the first corner guide hole CGH1 to press the pressing pad PPD. The second corner pressing rod CGB2 may pass through the second corner guide hole CGH2 to press the pressing pad PPD. The first corner pressing rod CGB1 and the second corner pressing rod CGB2 may press the corner portions RCP of the pressing pad PPD.

The first edge pressing rod LGB1 may pass through the first edge guide hole LGH1 to press the pressing pad PPD. The first edge pressing rod LGB1 may press the edge portion LNP of the pressing pad PPD.

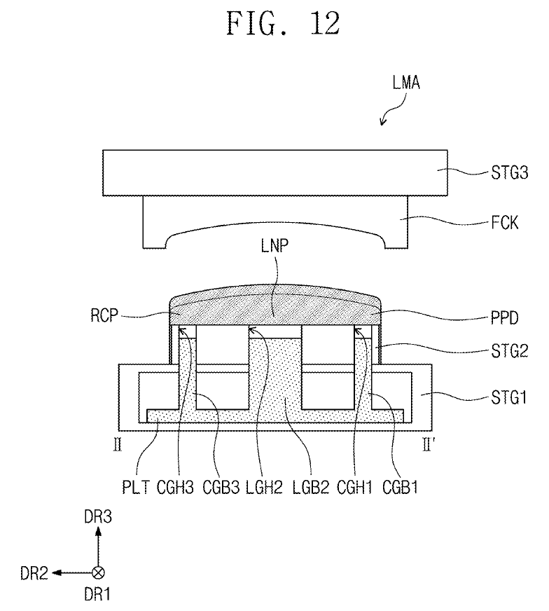

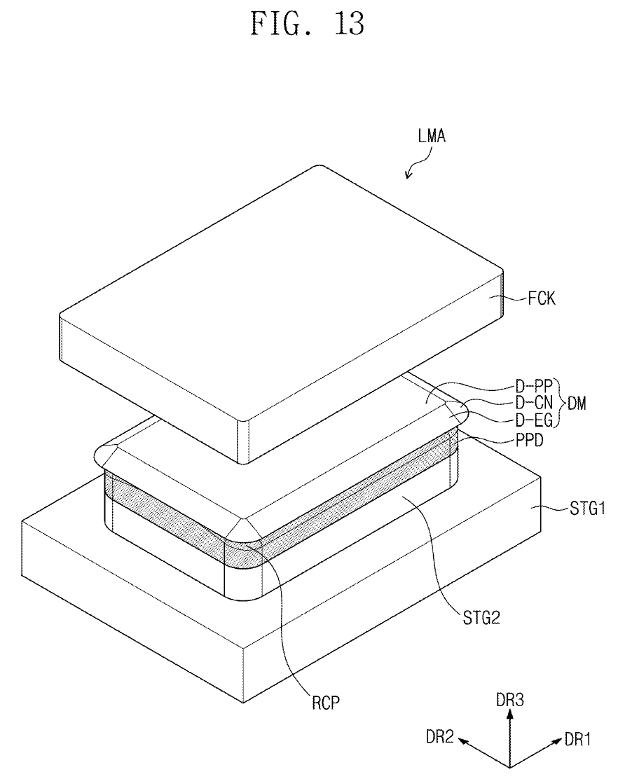

FIG. 12 is a cross-sectional view taken along the line II-II' in FIG. 7.

Referring to FIG. 12, the first corner pressing rod CGB1 may pass through the first corner guide hole CGH1 to press the pressing pad PPD. The third corner pressing rod CGB3 may pass through the third corner guide hole CGH3 to press the pressing pad PPD. The first corner pressing rod CGB1 and the third corner pressing rod CGB3 may press the corner portion RCP of the pressing pad PPD.

The second edge pressing rod LGB2 may pass through the second edge guide hole LGH2 to press the pressing pad PPD. The second edge pressing rod LGB2 may press the edge portion LNP of the pressing pad PPD.

FIG. 13 is a diagram illustrating a state in which a display module is disposed on a pressing pad for a process of bonding a display module and a window.

Referring to FIG. 13, a display module DM may be disposed on the pressing pad PPD. The display module DM may include a flat surface portion D-PP and an edge portion D-EG having a curved surface.

A window fixing chuck FCK may be disposed on the display module DM. Accordingly, the display module DM may be disposed between the window fixing chuck FCK and the pressing pad PPD.

When viewed on a plane, the display module DM may have a rounded shape. For example, the display module DM may have long sides extending parallel to the first direction DR1 and short sides extending parallel to the second direction DR2. Additionally, corners of the display module DM connecting the long sides and the short sides of the display module DM may have a curved shape and may be defined as rounded corners.

FIG. 14 is a diagram illustrating a portion of a bonding device according to an embodiment of the present disclosure. In FIG. 14, the first stage STG1 and the second stage STG2 are omitted. In FIG. 14, the edge pressing rods LGB and the corner pressing rods CGB are illustrated as being connected to the plate PLT and integrally formed, but an embodiment of the present disclosure is not limited thereto.

Referring to FIG. 14, the upper surfaces of the edge pressing rods LGB may have a rectangular shape when viewed on a plane. The upper surfaces of the corner pressing rods CGB may have an arc shape. The corner portions RCP of the pressing pad PPD may have a rounded shape. When the upper surfaces of the corner pressing rods CGB are formed in an arc shape and the corner pressing rods CGB press the corner portions RCP of the pressing pad PPD, the pressure applied to the corner portions RCP of the pressing pad PPD having a round shape may increase. As the pressure applied to the corner portions RCP of the pressing pad PPD increases, the pressure applied to corner portions D-CN of the display module DM may increase.

The corner portion RCP of the pressing pad PPD may separately press the curved surface of the corner portion D-CN of the display module DM. When the pressing pad PPD presses the display module DM, the curvature of the corner portion D-CN of the display module DM increases, thereby making it possible to reduce or eliminate air bubbles formed by the repulsive force of the display module DM due to a space formed between the corner portion of the display module DM and the window fixing chuck FCK.

Additionally, the corner portions RCP of the pressing pad PPD may separately press the corner portions D-CN of the display module DM. As a result of the pressure applied to the corner portions D-CN of the display module DM, the occurrence of a thickness deviation of the adhesive layer AL (see, e.g., FIG. 4) disposed between the display module DM and the window WIN (see, e.g., FIG. 4) at the corner portions D-CN of the display module DM caused by non-uniform pressure may be reduced or eliminated.

The corner pressing rods CGB and the edge pressing rods LGB press the pressing pad PPD multiaxially, and thus, a difference between the pressure applied to the corner portion RCP of the pressing pad PPD and the pressure applied to the edge portion LNP or the central portion CTP (see, e.g., FIG. 10) of the pressing pad PPD may decrease. Accordingly, uniform pressure is also transferred to the corner portion D-CN or the edge portion D-EG of the display panel DP, and thus, the process reliability of the display module DM may be improved.

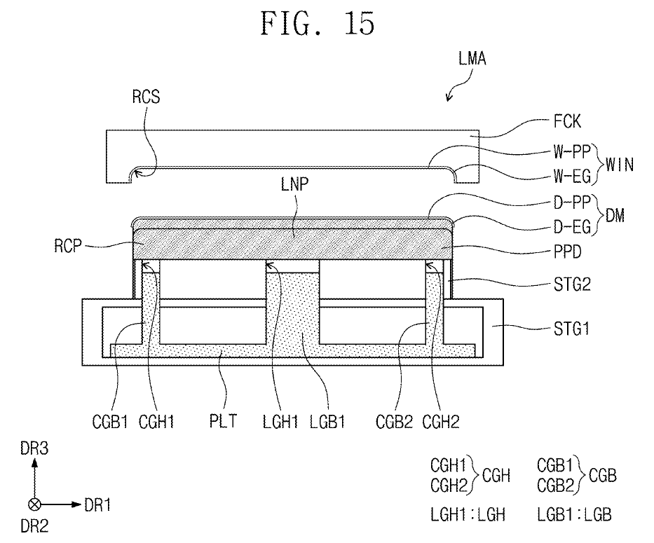

FIGS. 15 to 17 are diagrams illustrating a display panel bonding method according to an embodiment of the present disclosure. In FIGS. 15 to 17, for convenience of explanation, a first corner pressing rod CGB1, a second corner pressing rod CGB2, a first edge pressing rod LGB1, a first corner guide hole CGH1, a second corner guide hole CGH2, and a first edge guide hole LGH1 are illustrated.

Referring to FIG. 15, the display panel bonding method may include preparing (or providing) a first stage STG1 in which a plurality of edge pressing rods LGB and a plurality of corner pressing rods CGB are disposed. The display panel bonding method may include disposing, on the first stage STG1, a second stage STG2 in which a plurality of edge guide holes LGH and a plurality of corner guide holes CGH are defined.

Referring to FIGS. 7 and 15, the display panel bonding method may include disposing, on the second stage STG2, a pressing pad PPD having rounded corner portions RCP and having rounded edge portions LNP connecting the corner portions RCP when viewed on a plane. The display panel bonding method may include disposing the window fixing chuck FCK on the pressing pad PPD. The display panel bonding method may include disposing the window WIN on the recessed portion RCS defined in a lower surface of the window fixing chuck FCK. The recessed portion RCS may correspond to the rounded shape of the corner portion RCP of the pressing pad PPD. The display panel bonding method may include disposing the display module DM on the pressing pad PPD.

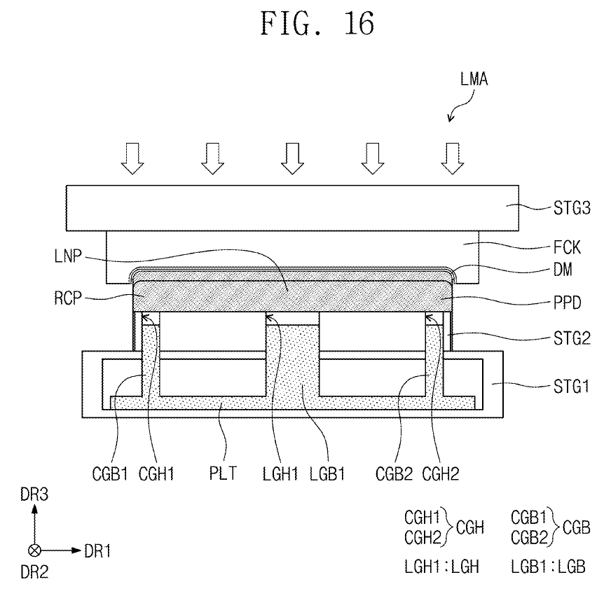

Referring to FIG. 16, the display panel bonding method may include bonding the window WIN and the display module DM. The display panel bonding method may include pressing the window WIN and the display module DM by the third stage STG3 disposed on the window fixing chuck FCK. The third stage STG3 may press the window WIN and the display module DM in a direction opposite to a third direction DR3. The third stage STG3 may press in the direction opposite to the third direction DR3, and therefore, uniform pressure may be transferred to the window WIN and the display module DM to press the window and the display module DM.

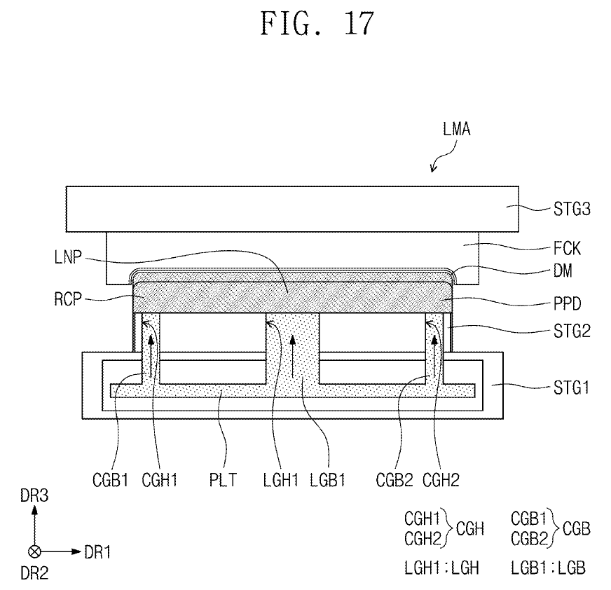

Referring to FIGS. 16 and 17, the display panel bonding method may include pressing the edge portion LNP of the pressing pad PPD by the edge pressing rods LGB respectively passing through the edge guide holes LGH and pressing the corner portions RCP of the pressing pad PPD by the corner pressing rods CGB respectively passing through the corner guide holes CGH.

The display panel bonding method may include pressing the window WIN and the display module DM by the third stage STG3 after the pressing of the edge portions LNP of the pressing pad PPD by the edge pressing rods LGB respectively passing through the edge guide holes LGH and the pressing of the corner portions RCP of the pressing pad PPD by the corner pressing rods CGB respectively passing through the corner guide holes CGH.

According to the description above, a corner portion of a pressing pad may separately press a curved surface of a corner portion of a display module. When the pressing pad presses the display module, the curvature of the corner portion of the display module increases, and accordingly, air bubbles formed by the repulsive force of the display module due to a space formed between the corner portion of the display module and a window fixing chuck may be reduced or eliminated.

Additionally, the corner portion of the pressing pad may separately press the corner portion of the display module. The pressure applied to the corner portion of the display module may reduce or eliminate the occurrence of thickness deviation at the corner portion of the display module due to non-uniform pressure of the adhesive layer disposed between the display module and the window.

In the above, description has been made with reference to embodiments of the present disclosure, but those skilled or of ordinary skill in the art may understand that various modifications and changes may be made to the present disclosure insofar as such modifications and changes do not depart from the spirit and technical scope of the present disclosure set forth in the claims and their equivalents to be described later.

Therefore, the technical scope of the present disclosure is not to be limited to the contents stated in the detailed description of the specification but should be determined by the claims and their equivalents.

What is claimed is:

1. A bonding device comprising:
a first stage comprising a plurality of edge pressing rods and a plurality of corner pressing rods;
a second stage on the first stage and having a plurality of edge guide openings and a plurality of corner guide openings;
a pressing pad on the second stage; and
a window fixing chuck on the pressing pad,
wherein, when viewed on a plane, the edge pressing rods respectively pass through the edge guide openings and the corner pressing rods respectively pass through the corner guide openings.

2. The bonding device of claim 1, wherein the edge pressing rods and the corner pressing rods are integrally formed.

3. The bonding device of claim 1, wherein the edge pressing rods and the corner pressing rods are configured to independently reciprocate in a vertical direction.

4. The bonding device of claim 1, wherein the pressing pad has corner portions, edge portions between the corner portions, and a central portion surrounded by the corner portions when viewed on the plane, and
wherein the corner portions are configured to be controlled independently from the edge portions and the central portion.

5. The bonding device of claim 4, wherein the central portion is higher than the corner portions and the edge portions.

6. The bonding device of claim 1, wherein, when viewed on the plane, the edge guide openings and the corner guide openings are alternately arranged along a circumferential direction of the second stage.

7. The bonding device of claim 1, wherein, when viewed on the plane, upper surfaces of the edge pressing rods have a rectangular shape and upper surfaces of the corner pressing rods have an arc shape.

8. The bonding device of claim 1, wherein, when viewed on the plane, at least one of the edge guide openings is between the corner guide openings in a circumferential direction of the second stage.

9. The bonding device of claim 1, further comprising a chamber in which the first stage, the second stage, the pressing pad, and the window fixing chuck are mounted.

10. The bonding device of claim 1, wherein, when viewed on the plane, a corner portion of the pressing pad has a rounded shape.

11. The bonding device of claim 10, wherein, when viewed on the plane, an edge portion connecting the corner portion of the pressing pad has a rounded edge shape.

12. The bonding device of claim 10, wherein a lower surface of the window fixing chuck has a recessed portion therein, and
wherein the recessed portion corresponds to the rounded shape of the pressing pad.

13. A display panel bonding method comprising:
preparing a first stage having a plurality of edge pressing rods and a plurality of corner pressing rods;
disposing, on the first stage, a second stage having a plurality of edge guide openings and a plurality of corner guide openings;
disposing, on the second stage, a pressing pad having corner portions having a rounded shape and having edge portions connecting the corner portions having a rounded edge shape when viewed on a plane;
disposing a window fixing chuck on the pressing pad;
disposing a window on a recessed portion in a lower surface of the window fixing chuck;
disposing a display module on the pressing pad;
bonding the window and the display module;
pressing the window and the display module by a third stage on the window fixing chuck; and
pressing the edge portion of the pressing pad by the edge pressing rods respectively passing through the edge guide openings and pressing the corner portions of the pressing pad by the corner pressing rods respectively passing through the corner guide openings.

14. The display panel bonding method of claim 13, further comprising pressing the window and the display module by the third stage after the pressing of the edge portions of the pressing pad by the edge pressing rods and the pressing of the corner portions of the pressing pad by the corner pressing rods.

15. The display panel bonding method of claim 13, wherein the edge pressing rods and the corner pressing rods integrally reciprocate in a vertical direction.

16. The display panel bonding method of claim 13, wherein the edge pressing rods and the corner pressing rods each independently reciprocate in a vertical direction.

17. The display panel bonding method of claim 13, wherein, when viewed on the plane, upper surfaces of the edge pressing rods have a rectangular shape and upper surfaces of the corner pressing rods have an arc shape.

18. The display panel bonding method of claim 13, wherein, when viewed on the plane, at least one of the edge guide openings is between the corner guide openings in a circumferential direction of the second stage.

19. An electronic device comprising a window and a display module, wherein the window and the display module are bonded by:
preparing a first stage having a plurality of edge pressing rods and a plurality of corner pressing rods;
disposing, on the first stage, a second stage having a plurality of edge guide openings and a plurality of corner guide openings;
disposing, on the second stage, a pressing pad having corner portions having a rounded shape and having edge portions connecting the corner portions having a rounded edge shape when viewed on a plane;
disposing a window fixing chuck on the pressing pad;
disposing the window on a recessed portion defined in a lower surface of the window fixing chuck;
disposing the display module on the pressing pad;
bonding the window and the display module;
pressing the window and the display module by a third stage on the window fixing chuck; and
pressing the edge portions of the pressing pad by the edge pressing rods respectively passing through the edge guide openings and pressing the corner portions of the pressing pad by the corner pressing rods respectively passing through the corner guide openings.
